(19) United States
(12) Patent Application Publication
(10) Pub. No.: US 2014/0147684 A1
(43) Pub. Date: May 29, 2014

(54) GAS BARRIER FILM AND METHOD OF PREPARING THE SAME

(71) Applicant: KOREA INSTITUTE OF SCIENCE AND TECHNOLOGY, Seoul (KR)

(72) Inventors: Soonjong KWAK, Seoul (KR); Jae Ho JUN, Gyeonggi-do (KR); Ju Young YOOK, Seoul (KR)

(73) Assignee: KOREA INSTITUTE OF SCIENCE AND TECHNOLOGY, Seoul (KR)

(21) Appl. No.: 14/090,524

(22) Filed: Nov. 26, 2013

(30) Foreign Application Priority Data
Nov. 26, 2012 (KR) 10-2012-0134859
Nov. 1, 2013 (KR) 10-2013-0132527

(51) Int. Cl. C09D 5/00; H01L 23/29

(52) U.S. Cl. CPC C09D 5/00; H01L 23/296
USPC 428/447; 427/535; 524/261

(57) ABSTRACT

Provided are a gas barrier film that is simply and economically manufactured, and has high hardness and strength, excellent gas blocking properties, controllable refraction index and transparency, and a compositionally gradient structure, and a method of producing the same. The gas barrier film includes a base material; and an organic/inorganic hybrid gas barrier layer that is formed on the base material and has a composition-gradient structure. The organic/inorganic hybrid gas barrier layer has a network structure having —O—Si—O— linkages. The network structure contains an organic functional group having a carbon atom directly linked to a silicon atom of the —O—Si—O— linkages, and other element that exists in an oxide form in the interstitial location of the network structure or that is linked to an oxygen atom of the —O—Si—O— linkages, wherein the other element comprises at least one selected from alkali metal, alkaline earth metal, transition metal, post transition metal, metalloid, boron, and phosphorous.

### CROSS-REFERENCE TO RELATED PATENT APPLICATION

This application claims the benefit of Korean Patent Application Nos. 10-2012-0134859, filed on Nov. 26, 2012 and 10-2013-0132527, filed on Nov. 1, 2013, in the Korean Intellectual Property Office, the disclosure of which is incorporated herein in its entirety by reference.

### BACKGROUND OF THE INVENTION

1. Field of the Invention

The present invention relates to a gas barrier film and a method of manufacturing the same. In particular, the present invention relates to a gas barrier film that includes a gas barrier layer that is stacked on a base material and has an organosilane network structure and a method of manufacturing the same.

2. Description of the Related Art

Due to increased requirements for thin and light-weight information communication devices, such as LCD, mobile phones, notebook computers, and commercialization of solar cells and flexible displays, a demand for light, transparent, and flexible base materials, which can be used instead of a typical glass substrate, is high, and research into applications including such base materials is very actively performed.

Glass substrates, which are used in typical display devices, have small coefficients for linear expansion, excellent gas blocking properties, high light transmittance, surface flatness, and excellent thermal resistance and chemical resistance. However, they are highly likely to crack when exposed to impact, and are heavy due to high density. Accordingly, it is difficult to manufacture thin, light-weight, flexible, and impact-resistance and splinterless display panels. As an alternative to a glass substrate, a transparent plastic film has been introduced.

For use as a substrate, a plastic film needs to have a high glass transition temperature for enduring a process temperature of a transistor device and a deposition temperature of a transparent electrode, oxygen and water vapor blocking characteristics to prevent aging of liquid crystals and organic luminescent materials, small coefficients of linear expansion and dimensional stability for the prevention of distortion of a substrate according to a process temperature change, high mechanical strength with compatibility with a process device used in a typical glass substrate, chemical resistance for enduring an etching process, high light transmittance, small birefringence, and surface scratching resistance. However, high-performance polymer base material films (including a polymer-inorganic composite film) complying with such conditions do not exist. Accordingly, to comply with such conditions, a polymer base material film is functionally coated with many layers. As an example of a coating, a planarization thin film that reduces defects of a polymer surface and provides planarity, a gas barrier thin film formed of an inorganic material to prevent permeation of oxygen and water vapor, or a silicon-based inorganic hard coating that provides scratch-resistance properties to a surface thereof may be used.

As a material for use in a gas barrier thin film, any one of various organic or inorganic materials that have, in addition to the gas blocking properties, high light transmittance, surface hardness, and heat resistance required in consideration to characteristics of a display panel may be used. Typically, a transparent inorganic material, such as silicon oxide (SiOₓ), aluminum oxide (AlₓO_{y}), or titanium oxide (TiOₓ), may be used. These materials may be coated on a surface of a plastic film by using, in general, a vacuum deposition method, such as plasma-enhanced chemical vapor deposition (PECVD) or sputtering, or a sol-gel method. A gas blocking thin film may have a single-layer structure formed of an inorganic material, a two-layer structure including an organic layer and an inorganic layer, a three-layer structure of organic layer/inorganic layer/organic layer or inorganic layer/organic layer/inorganic layer, a structure in which the same layer is repeatedly formed a few times, or the like. Typically, a gas blocking thin film may have one or more inorganic layers. Herein, an organic layer may prevent spreading of thin film defects, which may occur in an inorganic layer, to a neighboring inorganic layer, rather than the prevention of permeation of gas.

When an inorganic layer is directly coated on a plastic film or an organic layer is directly coated on an inorganic layer, due to a difference in properties (thermal expansion coefficient, hardness, or the like) of the respective layers, cracks or exfoliation may occur at an interface thereof. Japanese Patent Publication Nos. 1994-031850 and 2005-119148 disclose that an inorganic layer is directly coated on a plastic film by sputtering. In this case, however, due to a difference in elastic modulus, thermal expansion coefficient, bending radius of the plastic film and the inorganic layer, when the layers are exposed to heat or repeating application of power from the outside, or when the layers are bent, an interface thereof may undergo stress and crack, thereby inducing exfoliation of layers. To prevent this, as disclosed in Japanese Patent Publication No. 2003-260749, an organic/inorganic hybrid gas barrier thin film having intermediate properties of the two materials can be added to therebetween to prevent a rapid property change at the interface. However, even when the organic/inorganic hybrid gas barrier thin film is added, properties of the respective layers are not identical to each other, and the organic/inorganic composite layer and the inorganic layer also have a distinguishable interface. Accordingly, cracks and exfoliation occur.

Moreover, the formation of a typical gas blocking thin film requires a deposition process performed under high vacuum. Accordingly, expensive equipment is required and a long time is required to reach high vacuum, and thus, the typical gas blocking thin film formation is not economical. For example, Japanese Patent Publication No. 2004-082598 discloses use of a multi-layered gas blocking thin film including an organic layer and an inorganic layer. The disclosure teaches manufacturing of a product with excellent gas blocking properties. However, when complication and process costs for the multi-layered thin film are taken into consideration, commercialization thereof is not economical.

### SUMMARY OF THE INVENTION

The present invention provides a gas barrier film that is prepared by a simple and economic wet process without deposition under high vacuum or sputtering, that prevents cracking and interlayer exfoliation due to a large property difference (linear expansion coefficient and hardness) between a base material film and an inorganic layer, and that has excellent transparency and strength.

The present invention also provides a method of forming the gas barrier film.

According to an aspect of the present invention, a gas barrier film includes: a base material; and an organic/inorganic hybrid gas barrier layer that is formed on the base material and has a compositionally gradient structure, wherein the organic/inorganic hybrid gas barrier layer has a network structure comprising —O—Si—O— linkages, wherein the network structure contains an organic functional group having a carbon atom directly linked to a silicon atom of the —O—Si—O— linkages, and other element that exists in an oxide form in the interstitial location of the network structure or that is linked to an oxygen atom of the —O—Si—O— linkages, wherein the other element comprises at least one selected from alkali metal, alkaline earth metal, transition metal, post transition metal, metalloid, boron, and phosphorous.

According to another aspect of the present invention, a method of manufacturing a gas barrier film, includes: performing a sol-gel reaction on an organic/inorganic mixed solution including at least one organosilane represented by Formula 1 below, at least one silicate ester represented by Formula 2 below, and an oxide precursor of at least one other element selected from alkali metal, alkaline earth metal, transition metal, post transition metal, metalloid, boron, and phosphorous, to form a coating solution; coating and curing the coating solution on a base material to form an organic/inorganic hybrid precursor layer, and treating a surface of the organic/inorganic hybrid precursor layer with plasma of reactive gas to form an organic/inorganic hybrid gas barrier layer having a composition-gradient structure:

A¹ₗA²ₘA³ₙSi(OE¹)ₚ(OE²)_{q}(OE³)ᵣ [Formula 1]

Si(OG¹)_{α}(OG²)_{β}(OG³)_{γ}(OG⁴)_{δ} [Formula 2]

wherein in Formulae 1 and 2, A¹, A², and A³ are each independently a C1 to C20 alkyl group, a C1 to C20 fluoroalkyl group, a C6 to C20 aryl group, a vinyl group, an acryl group, a methacryl group, or an epoxy group,

l, m, and n are each independently an integer of 0 to 3 and satisfy 1≦l+m+n≦3,

E¹, E², and E³ are each independently a C1 to C10 alkyl group, a C1 to C10 fluoroalkyl group, a C6 to C20 aryl group, a C1 to C20 alkyloxyalkyl group, a C1 to C20 fluoroalkyloxyalkyl group, a C1 to C20 alkyloxyaryl group, a C6 to C20 aryloxyalkyl group, or a C6 to C20 aryloxyaryl group,

p, q, and r are each independently an integer of 0 to 3 and satisfy 1≦p+q+r≦3 and l+m+n+p+q+r=4,

G¹, G², G³, and G⁴ are each independently a C1 to C10 alkyl group, a C1 to C10 fluoroalkyl group, a C6 to C20 aryl group, a C1 to C20 alkyloxyalkyl group, a C1 to C20 fluoroalkyloxyalkyl group, a C1 to C20 alkyloxyaryl group, a C6 to C20 aryloxyalkyl group, or a C6 to C20 aryloxyaryl group, and α, β, γ, and δ are each independently an integer of 0 to 4 and satisfy the equation of α+β+γ+δ=4.

### BRIEF DESCRIPTION OF THE DRAWINGS

The above and other features and advantages of the present invention will become more apparent by describing in detail exemplary embodiments thereof with reference to the attached drawings in which:

FIG. 1 is a schematic cross-sectional view of a gas barrier film according to an embodiment of the present invention;

FIGS. 2A to 2C are schematic cross-sectional views of a gas barrier film according to another embodiment of the present invention;

FIG. 3 is a depth-profile graph of distribution of carbon, aluminum, silicon, and oxygen included in a gas barrier film according to an embodiment of the present invention, which was identified by X-ray electron beam spectroscopy (XPS); and

FIG. 4 is a scan electron microscopic image of a cross-section of a gas barrier film before and after an organic/inorganic hybrid gas barrier layer was formed in a method of forming a gas barrier film according to an embodiment of the present invention.

### DETAILED DESCRIPTION OF THE INVENTION

As used herein, the term “and/or” includes any and all combinations of one or more of the associated listed items.

Hereinafter, embodiments of the present invention are described in detail.

An aspect of the present invention provides a gas barrier film that includes a base material, and an organic/inorganic hybrid gas barrier layer that is disposed on the base material and has a compositionally gradient structure, wherein the organic/inorganic gas barrier layer has a network structure comprising —O—Si-β-linkages, wherein the net structure includes an organic functional group including a carbon atom directly linked to a silicon atom of the —O—Si—O— linkages, and other element that exists in an oxide form in an interstitial location of the network structure or is linked to an oxygen atom of the —O—Si—O— linkages and that includes at least one selected from alkali metal, alkali earth metal, transition metal, post-transition metal, metalloid, boron, and phosphorous.

Another aspect of the present invention provides a gas barrier film which has

an organic/inorganic hybrid gas barrier layer having compositionally gradient structure comprises an inorganic domain, an organic domain, and a gradient domain,

an inorganic domain is a domain of the organic/inorganic hybrid gas barrier layer which is away from the base material, and from which carbon is not substantially detected;

an organic domain gas is a domain of the organic/inorganic hybrid gas barrier layer which is near to the base material, and from which carbon is detected in a predetermined amount; and

a gradient domain is a domain of the organic/inorganic hybrid gas barrier layer that is interposed between the inorganic domain and the organic domain, and that has a carbon content gradually monotone-increasing in a thickness direction from the inorganic domain to the organic domain.

The wording that the gas barrier layer has a “compositionally gradient structure” means that in a thickness (depth) direction of the organic/inorganic hybrid gas barrier layer, a composition changes gradually in a gradient domain without any rapid change, and in a thickness direction of the organic/inorganic hybrid gas barrier layer away from an interface between the gas barrier layer and the base material, the gas barrier layer has a portion in which the ratio of carbon gradually decreases.

As described later, the gas barrier layer consists of three domains, and a composition thereof does not rapidly change at the domains.

The organic/inorganic hybrid gas barrier layer has a network structure comprising linkages of —O—Si—O—, which are shown in silicate. The network structure contains silicon, oxygen, hydrogen, carbon, and at least one other element, wherein some silicon atoms are directly linked to carbon atoms that constitute an organic functional group by covalent bond. For example, in the network structure, some silicon atoms may be linked to four oxygen atoms, and other silicon atoms may be linked to an organic functional group of an alkyl group, an aryl group, a fluoroalkyl group, a vinyl group, an acryl group, a methacryl group, or an epoxy group by Si—C bond.

In an embodiment of the present invention, a silicon atom of the network structure may be linked to at least one organic functional group by a Si—C bond.

The other element included in the network structure of the organic/inorganic hybrid gas barrier layer may be at least one element selected from alkali metal, alkaline earth metal, transition metal, post transition metal, metalloid, boron, and phosphorous (P). In the organic/inorganic hybrid gas barrier layer, the other element may exist in an oxide form in an interstitial location inside the network structure, or may be linked to a silicon atom constituting the skeleton of the network structure by the covalent bond of other element-oxygen-silicon form. That is, when the other element is referred to as M, some of the other element may exist in an oxide form of MₘOₙ (herein, m and n may be determined according to valence), a hydroxide form, or an oxide form containing a hydroxyl group in the interstitial location without a direct bond to the —O—Si—O— skeleton of the network structure. Some of the other elements may, like -M-O—Si— directly chemically bond to the skeleton of the network structure. Since the other element is bonded to an oxygen atom, the other element included in the organic/inorganic hybrid gas barrier film according to the present invention may be considered as an oxide.

The single-layered organic/inorganic hybrid gas barrier layer has a compositionally gradient structure, and includes an organic domain, a gradient domain, and an inorganic domain sequentially stacked in this stated order from the interface between the gas barrier layer and the base material.

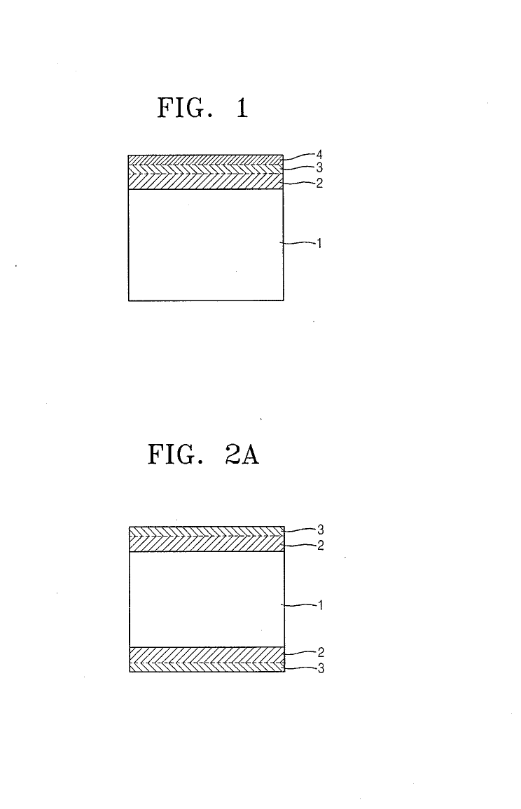

FIG. 1 is a cross-sectional view of an organic/inorganic hybrid gas barrier film according to an embodiment of the present invention. Referring to FIG. 1, a gas barrier film includes a base material 1 and an organic/inorganic hybrid gas barrier layer stacked on the based material 1, wherein the organic/inorganic hybrid gas barrier layer includes an organic domain 2, a gradient domain 3, and an inorganic domain 4. A “thickness” or “depth” direction of the organic/inorganic hybrid gas barrier layer used herein refers to a direction from the inorganic domain 4 to the organic domain 2 or the opposite direction thereof illustrated in FIG. 1.

An “inorganic domain” used herein refers to a domain of the organic/inorganic hybrid gas barrier layer which is located farther from the base material and from which carbon is not substantially detected. In terms of manipulation of a measurement device, the wording that carbon is not substantially detected in the inorganic domain can be identified by measuring a molar fraction of a carbon atom by, for example, X-ray photoelectron spectroscopy (XPS). A signal that is generally used in measuring the molar fraction of a carbon atom in XPS is a spectral signal induced from 1s energy level of a carbon atom. The wording that a carbon atom is not substantially detected in the inorganic domain based on XPS means that an intensity of the signal of a carbon atom is not statistically significantly greater than that of noise signals.

Typically, the inorganic domain includes as a major component, for example, silicon, oxygen, and an element other than carbon, which occupy 99% or more of all atoms constituting the inorganic domain. From the substantially non-detection of carbon in the inorganic domain, it is confirmed that the inorganic domain does not contain carbon that forms a Si—C bond with a silicon atom. However, the inorganic domain includes a silicon atom that is bonded to four oxygen atoms and forms an O—Si—O— linkage as the skeleton of the network structure. The inorganic domain of the gas barrier film plays a critical role in preventing permeation of gas due to its dense composition.

The “organic domain” used herein refers to a domain of the organic/inorganic hybrid gas barrier layer that is near to the base material, from which carbon is detected in a predetermined amount. Some silicon atoms of the organic domain are directly bonded to carbon atoms that constitute an organic functional group and form the —O—Si—O— linkage as the skeleton of the network structure, and other silicon atoms thereof are bonded to four oxygen atoms and are linked to the skeleton of the network structure. In addition, the organic domain includes other metal atoms described above. In embodiments of the present invention, the organic domain may allow the base material to tightly contact with the gas barrier layer based on its affinity with respect to the base material.

The “gradient domain” used herein refers to a domain of the organic/inorganic hybrid gas barrier layer that is interposed between the inorganic domain and the organic domain, and that has a carbon content gradually monotone-increasing in a thickness direction from the inorganic domain to the organic domain. That is, the carbon content of the gradient domain is substantially zero at the boundary between the gradient domain and the inorganic domain, gradually increases in the thickness direction, and at the boundary between the gradient domain and the organic domain, the carbon content increases up to a carbon content of the organic domain.

Since carbon is not substantially detected in the inorganic domain, the inorganic domain is regarded as an inorganic material layer that contains, as a major component, silicon, oxygen, and the other element described above, and although the organic domain is named as an organic domain herein, the organic domain may also include silicon, oxygen, and the other element described above, and as described later, some silicon atoms may not be bonded to an organic functional group. Accordingly, the organic domain may also be regarded as having an organic/inorganic composite material structure including an organic functional group and an inorganic material. The gradient domain may also be regarded as having an organic/inorganic composite material.

The compositionally gradient structure is a structure in which the carbon content changes in a thickness (depth) direction of the gas barrier layer, and amounts of oxygen, silicon and the other element do not change as much as that of carbon. In an embodiment of the present invention, amounts of silicon and other element in the gas barrier layer are substantially homogeneous in the organic/inorganic hybrid gas barrier layer. In detail, amounts of silicon and other element in the organic/inorganic hybrid gas barrier layer change within ±5 wt % in the thickness direction of the organic/inorganic hybrid gas barrier layer.

The organic/inorganic hybrid gas barrier layer having a compositionally gradient structure according to an embodiment of the present invention includes the inorganic domain, the gradient domain, and the organic domain, and the inorganic domain, the gradient domain, and the organic domain have boundaries that are not distinguishable from each other. Since the organic/inorganic hybrid gas barrier layer has a compositionally gradient structure in which a composition thereof gradually change in the gradient domain, due to the dense composition of the inorganic domain, excellent gas blocking effects and high mechanical strength are obtained, due to the gradient domain, a rapid change of properties may be buffered to secure flexibility, and due to the organic domain, high affinity with a base material may be obtained. In addition, since a composition gradually changes in a layer that is integrated by a chemical bond, the inorganic domain is not exfoliated from the gradient domain, and likewise, the gradient domain is not exfoliated from the organic domain. In embodiments of the present invention, the organic/inorganic hybrid gas barrier layer may less experience cracks and exfoliation resulting from a difference in properties of layers than a typical gas barrier film including a multi-layered gas barrier layer formed by stacking a layer of an inorganic material separately on a layer of an organic material by chemical deposition or sputtering, and also the organic/inorganic hybrid gas barrier film according to embodiments of the present invention may also have flexibility and strength.

Furthermore, in the organic/inorganic hybrid gas barrier film according to an embodiment of the present invention, elements other than carbon are directly linked to the —O—Si—O— skeleton of the organic/inorganic hybrid gas barrier layer via oxygen, or exist in the interstitial location of the network structure of the organic/inorganic hybrid gas barrier layer. Accordingly, more dense structure may be obtained, and surface hardness is substantially increased. In addition, a refractive index of the organic/inorganic hybrid gas barrier layer is controlled by appropriately controlling the kind and amount of other element. For example, when there is a target refractive index for the organic/inorganic hybrid gas barrier layer, an oxide of other element having a refractive index closer to the target refractive index than a refractive index of the organic/inorganic hybrid gas barrier layer formed without the other element, can be selected, and the selected other element is added to the organic/inorganic composite layer to obtain a refractive index more closer to the target refractive index.

Since the gas barrier film according to an embodiment of the present invention has the organic/inorganic hybrid gas barrier layer with a network structure having —O—Si—O— linkages as a skeleton, a transparent gas barrier layer can be formed according to selection of other elements. In an embodiment of the organic/inorganic hybrid gas barrier layer, amounts of components including the other element are determined in such a way that a refractive index of the organic/inorganic hybrid gas barrier layer is in a range of about 1.1 to about 2.5, for example, 1.4 to 2.5 with respect to light having a wavelength of 632 nm at the temperature of 25° C., and a light transmittance of the organic/inorganic hybrid gas barrier layer is 80% or more with respect to light having a wavelength of 550 nm at the temperature of 25° C. In the case of a display apparatus manufactured by using the organic/inorganic hybrid gas barrier layer having the refractive index of about 1.1 to about 2.5 according to an embodiment of the present invention, when a layer with material properties, different from those of the gas barrier film, is stacked (for example, a hard coating layer or a gas barrier layer formed of an inorganic material is further stacked, or a conductive inorganic layer is further stacked), matching of their refractive indexes is easy and thus, a final display apparatus has excellent light transmittance characteristics. In addition, when the light transmittance of the gas barrier film is 80% or more, clearance of, for example, a display apparatus may be improved. For example, a light transmittance of the gas barrier film may be 85% or more. Actually, however, the light transmittance of the gas barrier film may be about 90% or less in consideration of costs and limitation of properties of a source material. However, the light transmittance of the gas barrier film may also be higher than 90%, and is not limited thereto.

In an embodiment of the gas barrier film, the other element may be at least one selected from Li, Na, K, Rb, Cs, Be, Mg, Ca, Sr, Ba, Ti, Zr, Hf, V, Nb, Mo, W, Te, Re, Ni, Zn, Al, Ga, In, Tl, Sn, B, and P.

In an embodiment of the gas barrier film, an atomic number ratio of the other element to silicon in the organic/inorganic hybrid gas barrier layer is in a range of 1:20 to 20:1. When the atomic number ratio of the other element to silicon is within this range, the organic/inorganic hybrid gas barrier layer may have a dense structure and thus, excellent gas blocking characteristics may be embodied.

Also, in an embodiment of the gas barrier film, the carbon content of the inorganic domain may satisfy the following relationship:

$$\frac{{N}_{carbon}}{{N}_{silicon} + {N}_{oxygen} + {N}_{other element} + {N}_{carbon}} \leq 0.05$$

wherein N_{carbon} is the number of carbon atoms, N_{silicon} is the number of silicon atoms, N_{oxygen} is the number of oxygen atoms, and N_{other element} is the number of the other element.

That is, an amount of carbon included in the inorganic domain may be a molar ratio of 5% or less, for example, 1% or less. In other words, 1% carbon corresponds to a level of noise signals of XPS and thus, carbon is not substantially detected. Although —Si—O—Si— or -M-O—Si— contributes to a dense network structure, an end functional group having a carbon-hydrogen (C—H) bond, such as Si—CH, or Si-alkyl, may function as a defect in the network structure and may deteriorate gas blocking characteristics. When an amount of the carbon atom is within this range, internal defects, which are generated due to a functional group with a carbon-hydrogen bond, may be minimized, the inorganic domain may have excellent gas blocking characteristics.

In an embodiment of the gas barrier film, a surface hardness of the inorganic domain is 6H or more when measured by using a pencil hardness tester.

The network structure of the organic/inorganic hybrid gas barrier layer may include both a silicon atom (inorganic silicon) that is not directly bonded to carbon constituting an organic functional group and a silicon atom (organic silicon) that is directly bonded to carbon constituting an organic functional group. In this regard, the organic domain of the organic/inorganic hybrid gas barrier layer may include only organic silicon, or according to another embodiment, the organic domain may include both organic silicon and inorganic silicon. In an embodiment of the gas barrier film, when a network structure of the organic domain includes a silicon atom (inorganic silicon) that is not directly bonded to carbon constituting an organic functional group, a maximum atomic number ratio of the inorganic silicon atom to a silicon atom (organic silicon) that is directly bonded to carbon constituting an organic functional group in the organic domain, that is, an organic silicon:inorganic silicon may be 1:10. When the atomic number ratio of the organic silicon to the inorganic silicon in the organic domain is within this range, the organic/inorganic hybrid gas barrier layer may retain an appropriate flexibility without cracking even when exposed to external stress.

In an embodiment of the gas barrier film, the organic functional group may be directly linked to a silicon atom by a Si—C bond and may not be bonded to an oxygen atom. For example, the organic functional group may be linked to a silicon atom, like R—Si, not RO—Si, wherein R is the organic functional group. An organic/inorganic hybrid gas barrier layer that does not contain an organic functional group bonded to an oxygen atom, as described above, may further increase light transmittance, and compared to when an organic functional group bonded to an oxygen atom, like RO—Si, is used, a higher dense may be obtained and thus, higher gas blocking performance may be obtained at the same thickness.

In an embodiment of the present invention, the number of organic functional groups directly bonded to a silicon atom (organic silicon) is 3 or less. For example, the number of organic functional groups directly bonded to organic silicon may be 2 or less. For example, the number of organic functional groups directly bonded to organic silicon may be 1.

In an embodiment of the present invention, the organic functional groups may be cross-linked. For example, the cross-linking may be a carbon-carbon single bond.

In an embodiment of the present invention, the base material may be formed of a polymer material or an organic composite material, which are typically used in the art. For example, the base material may be selected from polyethersulfone, polycarbonate, polyimide, polyarylate, polyethyleneterephthaiate, polyethylenenaphthalate, cycloolefin copolymer, epoxy resin, unsaturated polyester, and a polymer composite material.

In an embodiment of the present invention, a thickness of the organic/inorganic hybrid gas barrier layer may be in a range of about 0.1 μm to 10 μm.

The gas barrier film according to an embodiment of the present invention may have an oxygen transmission rate of 10⁻¹cm³/m²/day to 10⁻³ cm³/m²/day at the temperature of 35° C. in a relative humidity of 0%. In particular, the oxygen transmission rate of 10⁻² cm³/m²/day obtainable in an embodiment of the present invention is one order less than a minimum oxygen transmission rate obtainable by typical plasma-enhanced chemical vapor deposition (PECVD): 10⁻¹ cm³/m²/day.

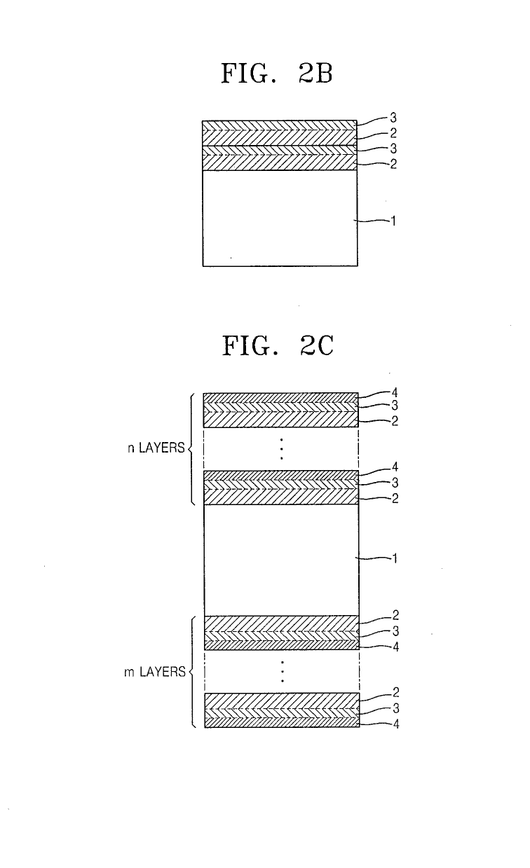

In the previous embodiment, a gas barrier film includes an organic/inorganic hybrid gas barrier layer stacked on one of surfaces of a base material. However, according to another embodiment of the present invention, a gas barrier film may include a plurality of organic/inorganic hybrid gas barrier layers. For example, according to embodiments of the present invention, as illustrated in FIG. 2A, a gas barrier film may include an organic/inorganic hybrid gas barrier layer stacked on both sides of a base material, as illustrated in FIG. 2B, a gas barrier film may include an organic/inorganic hybrid gas barrier layer that is double stacked on both surfaces of a base material, and as illustrated in FIG. 2C, m organic/inorganic hybrid gas barrier layers are stacked on a surface of a base material and n gas barrier layers are stacked on the other surface of the base material.

Another aspect of the present invention provides a method of manufacturing a gas barrier film as described above. The method includes the following processes:

preparing a coating solution by performing a sol-gel reaction on an organic/inorganic mixed solution including
at least one organosilane compound represented by Formula 1 below,
at least one silicate ester compound represented by Formula 2 below, and an oxide precursor of at least one other element selected from alkali metal, alkaline earth metal, transition metal, post transition metal, metalloid, boron, and phosphorous;

coating and curing the coating solution on the surface of a base material to form an organic/inorganic hybrid precursor layer; and

treating the surface of the organic/inorganic hybrid precursor layer with plasma to form an organic/inorganic hybrid gas barrier layer having a compositionally gradient structure:

A¹ₗA²ₘA³ₙSi(OE¹)ₚ(OE²)_{q}(OE³)ᵣ [Formula 1]

Si(OG¹)_{α}(OG²)_{β}(OG³)_{γ}(OG⁴)_{δ} [Formula 2]

In Formulae 1 and 2, A¹, A², and A³ are each independently a C1 to C20 alkyl group, a C1 to C20 fluoroalkyl group, a C6 to C20 aryl group, a vinyl group, an acryl group, a methacryl group, or an epoxy group,

l, m, and n are each independently an integer of 0 to 3, and satisfy 1≦l+m+n≦3,

E¹, E², and E³ are each independently a C1 to C10 alkyl group, a C1 to C10 fluoroalkyl group, a C6 to C20 aryl group, a C1 to C20 alkyloxyalkyl group, a C1 to C20 fluoroalkyloxyalkyl group, a C1 to C20 alkyloxyaryl group, a C6 to C20 aryloxyalkyl group, or a C6 to C20 aryloxyaryl group,

p, q, and r are each independently an integer of 0 to 3 and satisfy 1≦p+q+r≦3 and l+m+n+p+q+r=4,

G¹, G², G³, and G⁴ are each independently a C1 to C10 alkyl group, a C1 to C10 fluoroalkyl group, a C6 to C20 aryl group, a C1 to C20 alkyloxyalkyl group, a C1 to C20 fluoroalkyloxyalkyl group, a C1 to C20 alkyloxyaryl group, a C6 to C20 aryloxyalkyl group, or a C6 to C20 aryloxyaryl group, and

α, β, γ, and δ are each independently an integer of 0 to 4 and satisfy the equation of α+β+γ+δ=4.

In this regard, the plasma treatment is performed until a domain, which includes a contact surface with the plasma, and continues from the contact surface, is formed inside the organic/inorganic hybrid gas barrier layer, which has a thickness smaller than that of the organic/inorganic hybrid gas barrier layer, and from which carbon is not detected.

The oxide precursor may be a precursor that forms a diatomic oxide of the other element and oxygen by a sol-gel reaction.

The organosilane and silicate ester may include, as illustrated in Formula 1 and Formula 2, a hydrolyzable functional group, such as an alkoxy group and an aryoxy group at any stoichemically possible ratios. In the method according to embodiments of the present invention, the organosilane may further include, in addition to the alkoxy group and/or the aryloxy group, a non-hydrolyzable organic functional group, and in the organosilane, the non-hydrolyzable organic functional group and the hydrolyzable functional group may be used together in any stoichemically possible combination.

Hereinafter, the method of manufacturing the gas barrier film is described in detail.

The base material is not particularly limited, and may be a polymer material base material or an organic composite material base material. In an embodiment of the present invention, the base material may be any one of various materials that enable the formation of a film with excellent optical characteristics. In an embodiment of the present invention, examples of the base material are polyethylene terephthalate, biaxially-oriented polyethylene terephthalate (BOPET), polyethersulfone, polycarbonate, polyimide, polyarylate, polyethylenenaphthalate, epoxy resin, unsaturated polyester, low-density polyethylene (LDPE), middle-density polyethylene (MDPE), high-density polyethylene (HDPE), linear low-density polyethylene (LLDPE), biaxially-oriented polypropylene (BOPP), oriented polypropylene (OPP), cast polypropylene (CPP), biaxially-oriented polyamide (BOPA), cycloolefin copolymer, fiber reinforced plastics, glass, metal, and a composite material thereof.

The sol-gel reaction for the preparation of the coating solution from the organic/inorganic mixed solution is well known in the art, and is described in detail in references disclosed in the present application. Organosilane, and a hydrolyzable oxide precursor are all starting materials widely used for sol-gel reaction. To prepare an organic/inorganic mixed solution, organosilane, an oxide precursor that is to provide an oxide of an element other than carbon, and water are mixed and then hydrolyzed and condensed. In this regard, the organic/inorganic mixed solution may further include a solvent and a catalyst.

The oxide precursor of the other element may be other element ion, other element oxide ion, other element hydrogen oxide ion, other element hydroxide ion, which are formed by dissolving the other element in a solvent including water; other element hydroxide compound, other element alkoxy compound, other element oxo hydroxide compound, or other element oxo alkoxy compound, which are formed by hydrolysis of the other element in a solvent including water to form -M-O—Si—.

When the organic/inorganic mixed solution is sol-gel hydrolyzed and condensed, a hydrolyzable functional group, such as an alkoxy group or an aryloxy group, is hydrolyzed from organosilane components and thereafter, —O—Si—O— linkages for forming the final organic/inorganic hybrid gas barrier layer are connected to form a network structure. In this regard, if the oxide precursor of the other element includes a hydrolyzable functional group, the oxide precursor is also hydrolyzed, and linked to the —O—Si—O— linkages, or placed in an oxide form in the interstitial location of the network structure. In detail, when the oxide precursor of the other element is other element ion, other element oxide ion, other element hydrogen oxide ion, other element hydroxide ion, which are formed by dissolving the other element in a solvent including water, the oxide precursor may be thermally cured, ultraviolet-ray cured, or plasma-treated to form an oxide in which oxygen bonds to the other element in interstitial location inside and outside the network structure. Also, when the oxide precursor of the other element is other element hydroxide compound, other element alkoxy compound, other element oxo hydroxide compound, or other element oxo alkoxy compound, the oxide precursor may be thermally cured, ultraviolet-ray cured, or plasma-treated to directly chemically bond in the form of -M-O—Si— to the skeleton of the network structure to form a covalent bond, such as other element-oxygen-silicon.

Some oxide precursors of the other element may be converted into oxides in the subsequent plasma treatment. As a result of the hydrolysis and condensation, a coating solution that is an organic/inorganic mixed solution is formed. Since the organic/inorganic mixed solution is prepared by mixing at least one organosilane and at least one oxide precursor, various kinds of organic/inorganic mixed solutions can be formed. In another embodiment of the present invention, silicate ester and a polar solvent are mixed and an organosilane is added thereto while stirring the mixture to perform hydrolysis and condensation. From the organic/inorganic mixed solution, water, an alcohol component, or a catalyst are removed by extraction or dialysis, thereby finally preparing a coating solution.

In another embodiment of the present invention, organosilane and silicate ester used in preparing an organic/inorganic mixed solution are respectively represented by Formula 3 and Formula 4.

R¹ₓSi(OR²)₍₄₋ₓ₎ [Formula 3]

Si(OR³)₄ [Formula 4]

### In Formulae 3 and 4,

R¹ is a C1 to C20 alkyl group, a C1 to C20 fluoroalkyl group, a C6 to C20 aryl group, a vinyl group, an acryl group, a methacryl group or an epoxy group;

R² is a C1 to C10 alkyl group, a C1 to C10 fluoroalkyl group, a C1 to C20 alkyloxyalkyl group, or a C1 to C20 fluoroalkyloxyalkyl group; and

x is an integer of 1 to 3; and

R³ is a C1 to C10 alkyl group or a C1 to C20 alkyloxyalkyl group.

When organic trialkoxysilane and tetra-alkyl silicate respectively represented by Formulae 3 and 4 are used as organosilane and silicate ester, low material costs, ease of accessibility, and reactivity may be obtained.

In an embodiment of the present invention, as the organosilane of Formula 3, trialkoxysilane (R²Si(OR³)₃) obtained by substituting x of Formula 3 with 1 or dialkoxysilane ((R²)₂Si(OR³)₂) obtained by substituting x of Formula 3 with 2 may be used.

Non-limiting examples of trialkoxysilane (R²Si(OR³)₃) are methyltrimethoxysilane, methyltriethoxysilane, ethyltrimethoxysilane, ethyltriethoxysilane, propylethyltrimethoxysilane, methyltripropoxysilane, 3-glycidoxypropyltrimethoxysilane, 3-glycidoxypropyltriethoxysilane, 3-acryloxypropyltrimethoxysilane, 3-acryloxypropyltriethoxysilane, 3-metacryloxypropyltrimethoxysilane, 3-metacryloxypropyltriethoxysilane, vinyltriethoxysilane, vinyltrimethoxysilane, vinyltriethoxysilane, vinyltripropoxysilane, phenyltrimethoxysilane, 2-(3,4-epoxycyclohexyl)ethyltrimethoxysilane, and heptadecafluorodecyltrimethoxysilane.

Non-limiting examples of dialkoxysilane ((R²)₂Si(OR³)₂) are dimethyldimethoxysilane, dimethyldiethoxysilane, diethyldimethoxysilane, and diethyldiethoxysilane.

Examples of silicate ester of Formula 2 are tetraethyl orthosilicate (TEOS), tetramethyl orthosilicate, tetraisopropoxysilicate, tetrabutoxysilicate, and tetraethoxyethylsilicate, and other silicate esters may also be used, and silicate ester is not limited thereto.

In an embodiment of the present invention, in preparing the organic/inorganic mixed solution, a maximum molar ratio of organosilane to silicate ester is 1:10 or less. When the ratio of organosilane to silicate ester is within this range, an organic/inorganic hybrid gas barrier layer and an organic/inorganic hybrid gas barrier layer having a compositionally gradient structure may not crack when exposed to external stress and may have an appropriate level of flexibility. By controlling the ratio of organosilane to silicate ester, the carbon content in the final organic/inorganic hybrid gas barrier layer may be determined.

The other element, which is a major atom of the oxide precursor of the other element used for the organic/inorganic mixed solution, may be any one of various metal elements and metalloid elements, not carbon, that are hydrolyzed to form other element-oxygen-other element bond or other element-oxygen-silicon bond. Non-metal elements may also be used herein. Herein, ‘metal’ refers to a group consisting of alkali metal, alkaline earth metal, transition metal, post transition metal, metalloid, and non-metal.

An example of the oxide precursor used for the organic/inorganic mixed solution is presented below. The oxide precursor is not limited thereto.

Examples of a precursor of a non-metal other element are

in the case of boron (III), boric acid, and trimethyl borate; and

in the case of phosphorous (P), a phosphoric acid, phosphorus oxychloride, phosphorus pentoxide, and a C1 to C6 alkylphosphates (for example, methyl phosphate, ethyl phosphate, dimethyl phosphate, trimethyl phosphate, triethyl phosphate).

In an embodiment of the present invention, the oxide precursor may be a metal oxide precursor. In another embodiment of the present invention, the metal oxide precursor may be represented by Formula 5 below.

M-Lₙ [Formula 5]

In Formula 5, M is a metal selected from Li(I), Na(I), K(I), Rb(I), Cs(I), Be(II), Mg (II), Ca(II), Ti(IV), Ta(V), Zr(IV), Hf(IV), Mo(V), W(V), Zn(II), Al(III), Ga(III), In(III), Tl (III), Ge(IV), Sn(IV), and Sb(III). L is a (hydrolyzable) decomposable functional group, for example, halogen (F⁻¹, Cl⁻, Br⁻ and I⁻, in particular Cl⁻ and Br⁻¹), nitrate (NO₃⁻), a C1 to C6 alkoxy (in particular, methoxy, ethoxy, n-propoxy, i-propoxy and n-butoxy, i-butoxy, sec-butoxy or tert-butoxy, n-pentyloxy, n-hexyloxy), a C6 to C10 aryloxy (in particular, phenoxy), a C1 to C4 acyloxy (in particular, acetoxy and propionyloxy), alkylcarbonyl (for example, acetyl), or acetylacetone.

n in Formula 3 may be determined according to the oxidation number of metal, for example, in the case of Li(I), Na(I), K(I), Rb(I), and Cs(I), n=1, in the case of Be(II), Mg (II), Ca(II), and Zn(II), n=2, in the case of Al(III), Ga(III), In(III), Tl(III), B(III), and Sb(III), n=3, in the case of Ti(IV), Zr(IV), Hf(IV), Ge(IV), and Sn(IV), n=4, and in the case of Ta(V), Mo(V), and W(V), n=5.

In detail, examples of a precursor of alkali metals are in the case of Li(I), lithium acetate, lithium bromide, lithium carbonate, lithium chloride, lithium nitrate, and lithium iodide;

in the case of Na(I), sodium acetate, sodium bromide, sodium carbonate, sodium chloride, sodium nitrate, sodium iodide, sodium ethoxide, and sodium methoxide;

in the case of K(I), potassium acetate, potassium bromide, potassium carbonate, potassium chloride, potassium nitrate, and potassium iodide;

in the case of Rb(I), rubidium acetate, rubidium bromide, rubidium carbonate, rubidium chloride, rubidium nitrate, and rubidium iodide; and

in the case of Cs(I), cesium acetate, cesium bromide, cesium carbonate, cesium chloride, cesium nitrate, and cesium iodide.

Examples of a precursor of alkaline earth metals are,

in the case of Be(II), beryllium acetylacetonate, beryllium chloride, and beryllium nitrate;

in the case of Mg (II), magnesium acetate, magnesium bromide, magnesium carbonate, magnesium chloride, magnesium ethoxide, magnesium fluoride, magnesium formate, and magnesium iodide; and

in the case of Ca(II), calcium acetate, calcium bromide, calcium carbonate, calcium chloride, calcium fluoride, calcium formate, and calcium iodide.

Examples of a precursor of transition metals are

in the case of Ti(IV), titanium chloride dihydrate, titanium tert-butoxide, titanium n-butoxide, titanium 2-ethylhexyloxide, titanium ethoxide, titanium methoxide, titanium isopropoxide, and titanium iodide;

in the case of Ta(V), tantalum butoxide, tantalum chloride, tantalum ethoxide, and tantalum methoxide;

in the case of Zr(IV), zirconium butoxide, zirconium ethoxide, zirconium isopropoxide, zirconium propoxide, zirconium tert-butoxide, and zirconium acetylacetonate;

in the case of Hf(IV), hafnium n-butoxide, and hafnium tert-butoxide;

in the case of Mo(V), molybdenum isopropoxide, and molybdenum trichloride isopropoxide;

in the case of W(V), tungsten ethoxide; in the case of Zn(II), zinc citrate, zinc acetate, zinc acetylacetonate hydrate, zinc chloride, and zinc nitrate; and

in the case of Sn(IV), tin acetate (IV), tin chloride (IV) dihydrate, and tin tert-butoxide (IV).

Examples of post transition metals are

in the case of Al(II), aluminum ethoxide, aluminum isopropoxide, aluminum phenoxide, aluminum tert-butoxide, aluminum tributoxide, aluminum tri-sec-butoxide, aluminum chloride, and aluminum nitrate;

in the case of Ga(III), gallium acetylacetonate, gallium chloride, gallium fluoride, and gallium nitrate hydrate;

in the case of In(III), indium chloride, indium chloride tetrahydrate, indium fluoride, indium fluoride trihydrate, indium hydroxide, indium nitrate hydrate, indium acetate hydrate, indium acetylacetonate, and indium acetate; and

in the case of Tl(III), thallium acetate, thallium acetylacetonate, thallium chloride, thallium chloride tetrahydrate, thallium nitrate, and thallium nitrate trihydrate.

Examples of metalloids are in the case of Ge(IV), germanium ethoxide, germanium isopropoxide, germanium methoxide, germanium(IV) chloride, and germanium(IV) bromide, and in the case of Sb(III), antimony butoxide, antimony ethoxide, antimony methoxide, and antimony propoxide.

A sole-gel reaction of organosilane, silicate ester, and oxide precursor may enable formation of various organic/inorganic composite materials. For example, CaO—SiO₂, ZrO—SiO₂, MgO—SiO₂, Al₂O₃—SiO₂, TiO₂—SiO₂, ZnO₂—SiO₂, ZrO₂—SiO₂, Ga₂O₃—SiO₂, P₂O₅—SiO₂, P₂O₅—Na₂O—SiO₂, P₂O₅—Na₂O—Al₂O₃—SiO₂, P₂O₅—Al₂O₃—SiO₂, P₂O₅—CaO—Na₂O—SiO₂, B₂O₃—SiO₂, Na₂O—B₂O₃—SiO₂, GeO₂—SiO₂, MoO₂—SiO₂ may be formed. The principle and means of the sol-gel reaction are well known in the art (for example J. Am. Ceram. Soc. 71, 666 to 672 (1988), J. Am. Chem. Soc. 133, 1917 to 1934 (2011), Journal of Sol-Gel Science and Technology, 3, 219 to 227 (1994), J. Mater. Chem., 15, 2134 to 2140 (2005), Journal of Sol-Gel Science and Technology 13, 103 to 107 (1998), J Sol-Gel Sci Techn (2006) 39:79 to 83, Journal of Non-Crystalline Solids 100 (1988) 409 to 412, Journal of Sol-Gel Science and Technology 37, 63-68, 2006, J. Phys. Chem. B 1998, 102, 6465 to 6470, Catal Lett (2008) 126:286 to 292).

The amount of organosilane in the organic/inorganic mixed solution may vary according to the number of carbon atoms and the kind of the functional group included in a silane organic functional group, to prevent cracking of a layer coated on a base material and to provide flexibility to the layer. However, in an embodiment of the present invention, the organic/inorganic mixed solution may be prepared by mixing components with amounts satisfying the following relationship:

$$0.05 \leq \frac{{M}_{organosilane}}{{M}_{silicate ester} + {M}_{other element}} \leq 5$$

wherein M_{organosilane} is a molar number of organosilane, M_{silica ester} is a molar number of silicate ester, and H_{other element} is a molar number of the other element of the oxide precursor.

In general, M_{other element} may be the same as a molar number of the oxide precursor. However, when the number of the other element atoms in 1 mol oxide precursor is, like Li₂CO₃, an integer time of 1 (in the case that the oxide precursor is a non-stoichiometrical compound, a real time of 1), M_{other element} may be the corresponding integer time (the corresponding real time) of the molar number of the oxide precursor. For example, when the added oxide precursor is 2.5 mol Li₂CO₃, M_{other element} is 5. Likewise, when organosilane, silicate ester, and an oxide precursor are used together, M_{organosilane}, M_{silicate ester}, and M_{other element} are values obtained by adding corresponding chemical materials up.

When the amount of the organosilane is within this range, the coating solution coated on the base material may provide flexibility and also, the plasma treatment may be finished within a desired period of time.

The amount of the oxide precursor of the other element in the organic/inorganic mixed solution may vary according to a desired level of gas blocking characteristics and mechanical characteristics. However, in an embodiment of the present invention, components of the organic/inorganic mixed solution may be mixed in preparing the organic/inorganic mixed solution in such a way that the amount of the oxide precursor satisfies the following relationship:

$$0.1 \leq \frac{{M}_{other element}}{{M}_{organosilane} + {M}_{silicate ester}} \leq 10$$

wherein M_{organosilane} is a molar number of the organosilane, M_{silica ester} is a molar number of the silicate ester, and M_{other element} is a molar number of the other element of the oxide precursor.

M_{organosilane}, M_{silicate ester}, and M_{other element} are the same as defined with the previous relationship. When the oxide precursor of the other element is added at a ratio defined by the relationship with respect to silane components, the gas barrier film may not crack and may have excellent gas blocking characteristics and mechanical strength.

The organic/inorganic mixed solution according to embodiments of the present invention may further include water to perform hydrolysis and condensation. Any water may be allowable as long as the water has sufficient purity, and may be, for example, distilled water or ultrapure water. In an embodiment of the present invention, an amount of water may be in a range of about 5 to about 350 parts by weight based on 100 parts by weight of a total weight of organosilane, silicate ester, and the oxide precursor of the other element. In an embodiment of the present invention, a molar number n of water added to the organic/inorganic mixed solution may be equal to or higher than an equivalent with respect to a total molar number of hydrolyzable functional groups, such as an alkoxy group and an aryloxy group which are hydrolyzed in the organic/inorganic mixed solution. In another embodiment of the present invention, the organic/inorganic mixed solution may include 5 to 350 parts by weight of water or 10 to 250 parts by weight of water, based on 100 parts by weight of the organosilane compound, the silicate ester compound, and the oxide precursor. In an embodiment of the present invention, a molar number of water added to the organic/inorganic mixed solution may be equal to or greater than an equivalent amount with respect to the total molar number of hydrolyzable functional groups, such as an alkoxy group or an aryloxy group, in the organic/inorganic mixed solution.

In an embodiment of the present invention, in preparing the organic/inorganic mixed solution, components of the organic/inorganic mixed solution are mixed such that a ratio of a molar number of water to a molar number of hydrolyzable functional groups, such as an alkoxy group and an aryloxy group, of the organosilane and the silicate ester is in a range of 1:5 to 5:1, or 1:3 to 3:1. In this regard, even when the oxide precursor includes a hydrolyzable functional group, such as an alkoxy group and an aryloxy group, the molar number of the hydrolyzable functional group is a sum of the molar number of a hydrolyzable functional group of organosilane and silicate ester and the molar number of a hydrolyzable functional group of the oxide precursor.

To perform the sol-gel hydrolysis, the organic/inorganic mixed solution may further include a solvent, in addition to water that is a reactant. As a solvent included in the organic/inorganic mixed solution, a polar solvent may be used. Some examples of a polar solvent are alcohols, such as methanol, ethanol, isopropanol, butanol, 2-ethoxy-ethanol, 2-methoxyethanol, 2-buthoxy ethanol, 1-methoxy-2-propanol, or 1-ethoxy-2-propanol; ketones, such as methylethylketone or methylisobutylketone; esters, such as ethyl acetate, butyl acetate, 2-ethoxy-ethyl acetate, 2-methoxy-ethyl acetate, or 2-buthoxy-ethyl acetate; an aromatic hydrocarbon, such as toluene or xylene; and N,N-dimethylmethaneamide as a polar solvent. These solvents may be used alone or in combination in the organic/inorganic mixed solution.

The hydrolysis reaction may be accelerated by use of an acid or a base.

A catalyst that promotes hydrolysis may be an acid, such as a hydrochloric acid, a nitric acid, a sulfuric acid, an acetatic acid, hydrofluoric acid (HF), or ammonia.

The reaction time and temperature may vary according to the kinds of silane components and the oxide precursor, and their concentrations in the solvent. For example, the hydrolysis reaction may be performed under typical sol-gel reaction conditions of such silane components and the oxide precursor.

Reactants including an organosilane, silicate ester, the precursor compound of the other element, and water are sequentially mixed together with an additional solvent and an acid or base catalyst to perform a reaction at a reaction temperature of −20 to 120° C. for 5 minutes to 1 month, and thus, a sol-gel hydrolysis and a condensation reaction are performed, thereby forming an organic/inorganic mixed solution.

In this regard, regarding the sol-gel hydrolysis reaction, a hydrolyzable functional group, such as an alkoxy group or an aryloxy group, of organosilane and silicate ester components is hydrolyzed to form, for example, a Si—OH functional group, and regarding the condensation reaction, the Si—OH functional group is condensed while water is removed therefrom to link to —O—Si—O— linkages to form a network structure. The Si—OH functional group may contribute to an improvement in an interfacial adhesive force. In this regard, when the precursor compound of the other element includes a hydrolyzable functional group, the precursor compound is hydrolyzed and condensed to link to the —O—Si—O— linkages and placed in the interstitial location of the network structure. Some of the precursor compound of the other element may be converted into oxides even in the plasma treatment process.

As a result of the hydrolysis and condensation, an organic/inorganic mixed solution is formed.

A sol solid content of the finally prepared organic/inorganic mixed solution may be in a range of about 1 to about 50 wt %, for example, about 5 to about 30 wt % based on a solvent and water. When the amount of the organic/inorganic mixed solution is less than 1 wt %, a thickness is too small or even after a subsequent process, gas blocking characteristics may not be obtained. When the amount of the organic/inorganic mixed solution is greater than 50 wt %, the surface is rough and cracking may likely occur due to external impacts may easily occur.

The obtained organic/inorganic mixed solution may be coated on a base material by a typical coating method. In an embodiment of the present invention, the coating solution may be coated on a base material, for example, a transparent plastic film by spin coating, dip coating, roll coating, screen coating, spray coating, spin casting, flow coating, screen printing, or ink-jetting. In an embodiment of the present invention, after the base material is coated with the coating solution, a layer of the coating solution is cured by thermal curing or photo curing. In an embodiment of the present invention, the coating solution is coated on the base material to form a layer thereof having a thickness of about 0.1 to about 5 μm to form a precursor layer.

Thermal curing may be performed at a temperature that is equal to or lower than a temperature at which the transparent plastic film used as a base material is thermally deformed. The heat treatment conditions may vary according to the kind or thickness of a base material, and the kind of a solvent, and for example, the thermal curing may be performed in a range of about 100 to about 180° C.

Photo curing may be performed as long as the organosilane of Formula 1 in which R¹ is an unsaturated functional group, such as a vinyl group, an acryl group, a methacryl group, or the like is used as a source for sol/gel reaction. When exposed to light, radicals are generated from organosilanes with such functional groups and the unsaturated functional groups are cross-linked. Accordingly, an organic/inorganic hybrid gas barrier layer in which organic functional groups are cross-linked by irradiation to light may be formed. The photo curing may be performed by a typical photoinitiator, and examples of a suitable photoinitiator are, but are not limited thereto, 1-hydroxycyclohexylphenylketone (product name: Irgacure 184), benzophenone, 2-hydroxy-2-methylpropiophenone, 2,2-diethoxyacetophenone, and 3,3,4,4-tetra-(t-butylperoxycarbonyl)benzophenone. In this regard, the photoinitiator may be in a range of about 0.1 to about 6 parts by weight based on 100 parts by weight of the coating solution.

In the method described above, without chemical deposition or sputtering under high vacuum, a surface of the precursor layer coated on the base material is treated with plasma, thereby converting the precursor layer into the organic/inorganic hybrid gas barrier layer. Due to the plasma treatment, an inorganic domain and a gradient domain located therebelow in a depth direction of the inorganic domain are formed from the surface of the precursor layer. That is, the surface of the precursor layer containing a silane-derived organic functional group is plasma treated with a reactive gas to remove the organic functional group to convert a portion of the surface of the precursor layer into a pure inorganic material layer, and furthermore, in a region of the precursor layer corresponding to the gradient domain, a composition gradient of the organic functional group is formed in the depth direction to convert the precursor layer into the organic/inorganic hybrid gas barrier layer.

The conversion of the surface of an upper most portion of the precursor layer into the inorganic material domain in the plasma treatment is performed by simultaneous physical and chemical effects formed by plasma. Hereinafter, an operational principal of the method according to an embodiment of the present invention is to be described for ease of understanding. However, the present invention is not limited thereto. When a reactive gas (for example, oxygen) is used, due to chemical effects of plasma, an organic functional group present in a silicon chain in vicinity of the surface of the precursor layer decomposes and is removed therefrom in a gaseous form (CO, CO₂). Simultaneously, light energy with various wavelengths (soft X-ray, ultraviolet ray, visible ray, and infrared ray) generated during excitation-relaxation of gaseous molecules induced by plasma may cause a photochemical reaction at the surface of the precursor layer. In particular, when light with high energy, such as soft X-ray and vacuum ultraviolet ray (100 to 190 nm), is irradiated during the plasma treatment, Si—C, Si—O, and M-O bonds may decompose and radicals may be formed to realign molecules, thereby accelerating a cross-linking reaction. At the same time, since ions with high energy generated by the plasma treatment may induce pressure and heat during ion bombardment on a surface, a molecular structure in the treated surface region of the precursor layer is induced to have a dense structure.

Ultimately, due to the plasma treatment using a reactive gas, organic functional groups are effectively removed from the surface of the precursor layer to form an inorganic domain with a dense structure. Since the formed inorganic domain has a dense structure, excellent gas blocking effects may be obtained. The dense structure may be further enhanced due to an oxide of the other element. The inorganic domain with a dense structure has an increased surface hardness.

In addition, in a region of the precursor layer deeper than the surface region in which the inorganic domain is formed, the gradient domain is formed in which the organic functional group is not completely removed and a carbon concentration gradually increases in a thickness direction from the inorganic domain to the organic domain.

In an embodiment of the present invention, the plasma treatment is continuously performed at once without any change in plasma treatment conditions during the plasma treatment. That is, in forming the gradient domain, the precursor layer is continuously treated with plasma under constant treatment conditions without any change in plasma treatment conditions. By doing so, a gas barrier layer having the composition gradient-type structure described above is formed. However, according to performance of a gas barrier film, one of ordinary skill in the art may change plasma treatment conditions over time or may perform the plasma treatment intermittently several times.

In detail, the plasma surface treatment may be performed in such a way that the base material with the precursor layer at its surface is loaded into a plasma reaction chamber, a pressure of the chamber is decreased, a reactive gas (that is, a plasma source gas), such as O₂, N₂O, N₂, NH₃, H₂, or H₂O, is supplied, and then, power is applied to an electrode to generate plasma to treat the surface of the precursor layer. In this regard, the plasma source gas supplied into the reaction chamber may be, in addition to a single gas, a mixed gas of O₂/N₂O, O₂/N₂, O₂/NH₃, O₂/H₂, Ar/O₂, He/O₂, Ar/N₂O, He/N₂O, Ar/NH₃, or He/NH₃, or a mixed gas including an inert gas, such as helium (He) or argon (Ar). In addition, as a power source for the generation of plasma, any one of various plasma power sources including a radiofrequency (RF) power source, a medium frequency (MF) power source, a direct current (DC) power source, and microwave (MW) power source may be used.

A gas blocking performance of each of the inorganic domain and the gradient domain formed by the plasma surface treatment may be controllable according to plasma output, a treatment pressure, a treatment time, and a distance between an electrode and a substrate, and a reactive gas. In general, the higher plasma output, the lower treatment pressure, and the longer treatment time, the more hydrocarbon component is removed, the greater thickness the inorganic domain and the gradient domain have, and the higher gas blocking performance the organic/inorganic hybrid gas barrier layer has. Although high plasma output may contribute to a decrease in the treatment time to obtain high gas blocking performance, due to the temperature increase resulting from the treatment, an organic material used as a base material may be deformed. Accordingly, the plasma output and the treatment time need to be appropriately controlled. In addition, a bond, such as M-O or M-N (wherein M is silicon, or metal of the other element), may be formed according to a reactive gas to control gas blocking characteristics.

In an embodiment of the present invention, to obtain excellent gas blocking characteristics, the inorganic domain may be formed to have a thickness of about 10 to about 50 nm thickness. In an embodiment of the present invention, a total thickness of the inorganic domain and the gradient domain which are formed by the plasma treatment may be in a range of about 100 nm to about 200 nm.

The formed composition-gradient domain has intermediate characteristics of an organic material and an inorganic material according to a ratio of the organic functional group. Accordingly, the organic/inorganic composite layer may perform a buffering role between the base material that is an organic material and the inorganic domain formed by plasma treatment. Due to the buffering, when an external force is applied to the organic/inorganic hybrid gas barrier layer or when the organic/inorganic hybrid gas barrier layer shrinks or expands due to temperature, a stress occurring at the gradient domain is reduced and thus, cracks or exfoliation of the gas barrier film from the base material is suppressed.

In an embodiment of the present invention, when a radiofrequency (RF) power source is used as a plasma power source, a plasma treatment may be performed under conditions including a temperature of 0° C., a pressure of 1 atm, a gas flow of about 2 to about 7 sccm (standard cubic centimeter per minute), a power output of about 50 to about 600 W, a treatment time of about 10 seconds to about 10 minutes, and a treatment pressure of about 10 to about 500 mtorr. When the plasma output is less than 50 W, the treatment time of 10 minutes or less is not sufficient to obtain a gas blocking performance, and when the plasma output is higher than 600 W, a film may be damaged. In addition, when the plasma treatment pressure is greater than 500 mtorr or the treatment time is less than 10 seconds, a desired gas blocking performance may not be obtained.

As described in connection with FIG. 2, in a method of manufacturing a gas barrier film according to an embodiment of the present invention, the manufacturing process for a gas barrier layer is performed on a surface of a base material and then, the same process may be performed on the other surface of the base material, or the manufacturing process may be simultaneously performed on the both surfaces. Accordingly, according to the embodiments of the present invention described above, a single-layered organic/inorganic hybrid gas barrier layer may be formed on a surface of a transparent plastic film, a two or more-layered organic/inorganic hybrid gas barrier layer may be formed on a surface of a transparent plastic film, a single-layered organic/inorganic hybrid gas barrier layer may be formed on each of both surfaces of a transparent plastic film, or a two or more-layered organic/inorganic hybrid gas barrier layer may be formed on each of both surfaces of a transparent plastic film.

Another aspect of the present invention provides a substrate that is used to manufacture an electronic device, including a gas barrier film an embodiment of the present invention. The substrate may be a flexible substrate, such as a polymer substrate, and a material for forming the polymer substrate is polyamide, polyimide, polyethersulfone, polycarbonate, polyethylene naphthalate, polyester, polyethylene telephthalate, or a mixture thereof.

Another aspect of the present invention provides an electronic device including a gas barrier film an embodiment of the present invention. Examples of the organic electronic device are an organic thin film transistor, an organic light-emitting device, and an organic solar battery.

Another aspect of the present invention provides a packaging material including a gas barrier layer an embodiment of the present invention. An example of the packaging material is a gas blocking packaging material that includes a packaging base material and the organic/inorganic hybrid gas barrier layer stacked thereon. Since the stacking of the organic/inorganic hybrid gas barrier film according to an embodiment of the present invention on the packaging base material can be performed by plasma treatment following a wet coating as in the same way as used to form the gas barrier film, the method may be obvious to one of ordinary skill in the art. Accordingly, the packaging material will not be described in detail herein.

### Example

Hereinafter, embodiments of the present invention are described in detail with reference to examples. The examples are presented herein for illustrative purpose only and do not limit the scope of the present invention.

### Example 1

As a base material, a polyethyleneterephthalate (PET) film having a thickness of 200 μm, which is a transparent plastic, was used, and before an organic/inorganic composite layer was formed, a surface of the PET film was treated with plasma to enhance an adhesive force. The plasma surface treatment was performed as follows: the PET film was placed in a plasma chamber, and an internal pressure of the chamber was reduced by using a vacuum pump to 10⁻³ torr or lower, while the vacuum pump was operated, 5 sccm of argon gas was loaded thereinto to generate plasma at a pressure of 50 mtorr and a RF output of 100 W, and the surface of the PET film was plasma treated for a few minutes.

a) Preparation of Organic/Inorganic Mixed Solution and Formation of Precursor Layer

1.25 g (6 mmol) of tetraethyl orthosilicate (TEOS) and 1.07 g (6 mmol) of methyltriethoxysilane (MTES) was added to 12 mL of isopropanol solvent, and 1.23 g (6 mmol) of aluminum isopropoxide was added thereto, and then, 0.1 M hydrochloric acid aqueous solution was added thereto and the mixture was stirred for 30 minutes. The mixture was sol-gel hydrolyzed and condensed to obtain a sol of a coating solution in which an atomic ratio of Si:Al was 2:1, and the PET film was dip-coated by the coating solution to form a precursor layer.

b) Formation of Organic/Inorganic Hybrid Gas Barrier Layer

The PET film with the precursor layer formed thereon was placed in a plasma reaction chamber and an internal pressure of the chamber was reduced to 10⁻³ torr or lower by using a vacuum pump, and during the vacuum pump operated, 5 sccm of oxygen gas was loaded thereinto to generate plasma at the pressure of 50 mtorr and a RF output of 250 W to treat the surface of the film for 1 minute to remove hydrocarbon from the surface of the organic/inorganic hybrid gas barrier layer. Accordingly, obtained was a transparent gas barrier film including an organic/inorganic hybrid gas barrier layer having a compositionally gradient structure formed on a transparent plastic film.

### Example 2

A transparent gas barrier film was prepared in the same manner as in Example 1 except that 0.83 g (4 mmol) of TEOS and 1.54 g (8 mmol) of triethoxy(ethyl)silane (ETES) were added to 9 mL of isopropanol, and then, 4.08 g (12 mmol) of titanium(IV) butoxide was added thereto.

### Example 3

A transparent gas barrier film was prepared in the same manner as in Example 1 except that 1.25 g (6 mmol) of TEOS and 1.07 g (6 mmol) of MTES were added to 8 mL of n-butanol, and then, 1.09 g (4 mmol) of zirconium(IV) ethoxide was added thereto.

### Example 4

A transparent gas barrier film was prepared in the same manner as in Example 1 except that 1.25 g (6 mmol) of TEOS and 1.07 g (6 mmol) of MTES were added to 15 mL of ethanol, and then, 1.78 g (6 mmol) of zinc nitrate hexahydrate was added thereto.

### Example 5

A transparent gas barrier film was prepared in the same manner as in Example 1 except that 0.62 g (3 mmol) of TEOS and 1.07 g (6 mmol) of vinyltrimethoxysilane (VTMS) was added to 9 mL of n-propanol, and then, 0.26 g (1 mmol) of magnesium nitrate hexahydrate and 0.41 g (2 mmol) of aluminum isopropoxide were added thereto.

### Example 6

A transparent gas barrier film was prepared in the same manner as in Example 1 except that 1.25 g (6 mmol) of TEOS and 1.07 g (6 mmol) of isobutyltrimethoxysilane (IBTMS) were added to 7 mL of N,N-dimethylformamide, and then, 0.61 g (3 mmol) of aluminum isopropoxide and 0.19 g (3 mmol) of boric acid were added thereto.

### Example 7

A transparent gas barrier film was prepared in the same manner as in Example 1 except that 1.25 g (6 mmol) of TEOS and 1.15 g (6 mmol) of ETES were added to 8 mL of ethanol, and then, 0.15 g (2.4 mmol) of boric acid was added thereto.

### Example 8

A transparent gas barrier film was prepared in the same manner as in Example 1 except that 0.83 g (4 mmol) of TEOS and 1.43 g (8 mmol) of triethoxymethylsilane (MTES) were added to 11 mL of isopropanol, and then, 2.19 g (12 mmol) of triethyl phosphate were added thereto.

### Example 9

A transparent gas barrier film was prepared in the same manner as in Example 1 except that 1.25 g (6 mmol) of TEOS and 1.07 g (6 mmol) of ETES were added to 15 mL of n-propanol, and then, 0.30 g (1.71 mmol) of gallium (III) chloride was added thereto.

### Example 10

A transparent gas barrier film was prepared in the same manner as in Example 1 except that 1.67 g (8 mmol) of TEOS and 0.79 g (4 mmol) of trimethoxyphenylsilane (PTMS) were added to 12 mL of n-butanol, and then, 0.99 g (4 mmol) of aluminum sec-butoxide was added thereto.

### Example 11

A transparent gas barrier film was prepared in the same manner as in Example 1 except that 2.08 g (10 mmol) of TEOS and 0.50 g (2 mmol) of 3-(trimethoxysilyl)propyl methacrylate (TPSMA) were added to 10 mL of isopropanol, and then, 0.59 g (2.4 mmol) of aluminum sec-butoxide was added thereto. To the obtained sol, 1-hydroxycyclohexylphenylketone (DARACURE 184 manufactured by CIBA Company), which is a photo curing agent, was added thereto in an amount of 2 parts by weight based on 100 parts by weight of a sol solution to cross-link organic functional groups. The plasma treatment was performed in the same manner as in Example 1.

### Example 12

A transparent gas barrier film was prepared in the same manner as in Example 1 except that 1.67 g (8 mmol) of TEOS and 0.99 g (4 mmol) of TPSMA were added to 9 mL of n-butanol, and then, 0.51 g (2 mmol) of germanium(IV) ethoxide was added thereto.

### Example 13

A transparent gas barrier film was prepared in the same manner as in Example 1 except that 1.67 g (8 mmol) of TEOS and 0.99 g (4 mmol) of TPSMA were added to 7 mL of isopropanol, and then, 10.67 g (24 mmol) of thallium(III) nitrate trihydrate was added thereto.

### Example 14

A transparent gas barrier film was prepared in the same manner as in Example 1 except that 1.25 g (6 mmol) of TEOS and 1.07 g (6 mmol) of triethoxymethylsilane were added to 8 mL of isopropanol, and then, 0.62 g (6 mmol) of trimethylborate and 0.30 g (1.2 mmol) of magnesium nitrate were added thereto.

### Example 15

A transparent gas barrier film was prepared in the same manner as in Example 1 except that 1.67 g (8 mmol) of TEOS and 0.59 g (4 mmol) of VTMS were added to 14 mL of ethanol, and then, 1.23 g (3 mmol) tin(IV) tert-butoxide was added thereto.

### Example 16

A transparent gas barrier film was prepared in the same manner as in Example 1 except that 1.46 g (7 mmol) of TEOS and 0.96 g (5 mmol) of ETES were added to 7 mL of isopropanol, and then, 1.63 g (6 mmol) of zirconium(IV) ethoxide was added thereto.

### Example 17

A transparent gas barrier film was prepared in the same manner as in Example 1 except that 1.25 g (6 mmol) of TEOS and 1.07 g (6 mmol) of MTES were added to 9 mL of isopropanol, and then, 1.14 g (4 mmol) titanium(IV) isopropoxide was added thereto.

### Example 18

A transparent gas barrier film was prepared in the same manner as in Example 1 except that 0.83 g (4 mmol) of TEOS and 1.54 g (8 mmol) of ETES were added to 9 mL of n-butanol, and then, 0.59 g (2.4 mmol) of aluminum sec-butoxide was added thereto.

### Example 19

A gas barrier film was formed such that an organic/inorganic hybrid gas barrier layer was formed in the same manner as in Example 18, and then, the same process was performed once thereon, thereby forming two organic/inorganic hybrid gas barrier layers on a surface of a polymer base material.

### Example 20

A gas barrier film was formed such that an organic/inorganic hybrid gas barrier layer was formed in the same manner as in Example 18, and then, the same process was performed once on a surface of a polymer base material opposite to where the organic/inorganic hybrid gas barrier layer was formed, thereby forming the organic/inorganic hybrid gas barrier layer on both surfaces of the polymer base material.

### Example 21

A transparent gas barrier film was prepared in the same manner as in Example 1 except that 1.67 g (8 mmol) of TEOS and 0.99 g (4 mmol) of 3-(methacryloyloxy)-propyl)-trimethoxysilane (MPTMS) were added to 9 ml of 1-methoxy-2-propanol, and then, 0.45 g (1.2 mmol) of aluminum nitrate 9 hydroxide was added thereto.

### Comparative Example 1

A gas barrier film was prepared in the same manner as in Example 1 except that 1.176 g (6 mmol) of TEOS and 1.07 g (6 mmol) of MTES were added to 5 mL of isopropanol and an oxide precursor was not used.

### Comparative Example 2

A gas barrier film was formed such that an organic/inorganic hybrid gas barrier layer was formed in the same manner as in Example 1 and then, the plasma treatment was omitted to form a gas barrier film.

### Comparative Example 3

A precursor layer was formed in the same manner as in Example 1, and then, a vacuum deposition apparatus was used to form a SiOₓ gas barrier film having a thickness of about 30 nm by PECVD under a vacuum of 1×10⁵ torr.

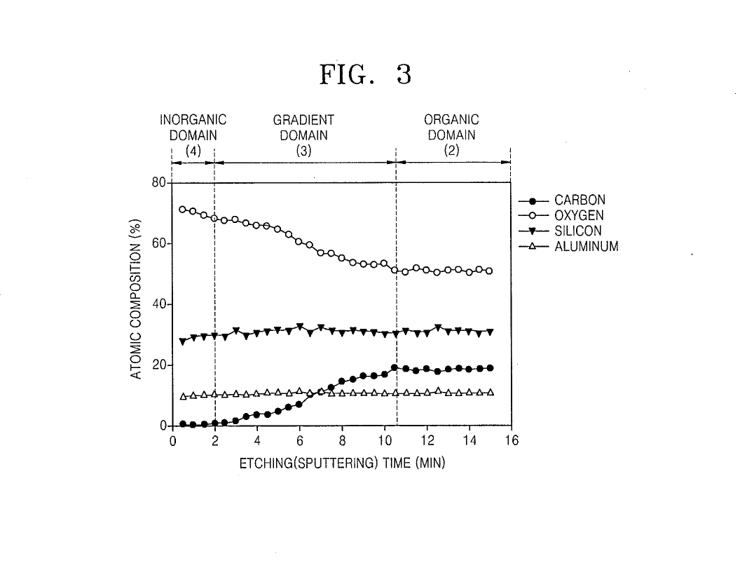

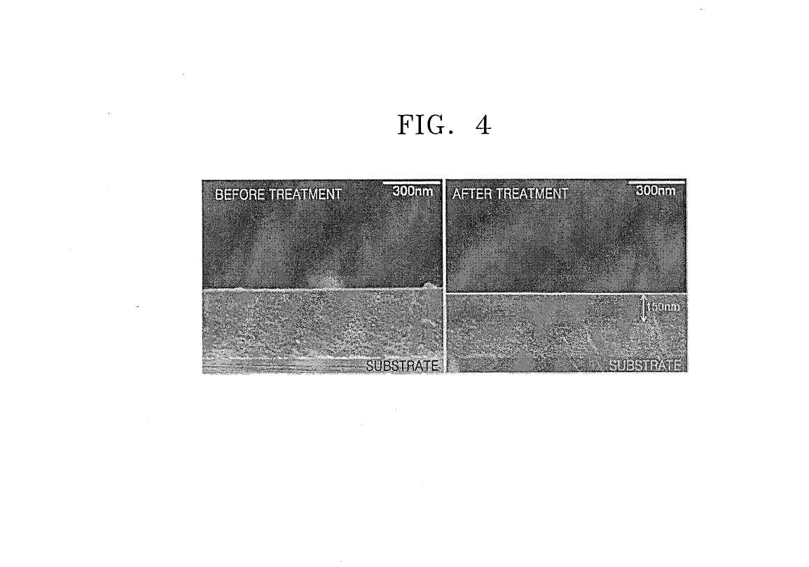

To identify a structure of a gas barrier film formed by using a method of forming a gas barrier film according to an embodiment of the present invention, a cross-section of the gas barrier film prepared according to Example 1 was identified and a composition change according to a depth was measured. Results thereof are shown in FIGS. 3 and 4.

FIG. 3 is a depth-profile showing a composition of elements obtained by performing XPS analysis by sputtering the surface of the organic/inorganic hybrid gas barrier layer of the gas barrier film prepared according to Example 1 with 3.5 keV of Ar⁺ ions in a depth direction. As apparent in FIG. 3, carbon was not substantially detected in a surface of the organic/inorganic hybrid gas barrier layer away from the base material, and an inorganic domain mainly formed of aluminum, silicon and oxygen, a gradient domain in which the carbon content gradually increases, and an organic domain in which carbon is detected were distinctively identified. As apparent in FIG. 3, content changes of silicon and aluminum as the other element were made within a maximum of ±5 wt % in a thickness direction of the organic/inorganic hybrid gas barrier layer. In addition, since a composition value is not dramatically changed in the graph of FIG. 3, it was confirmed that the three domains are not distinctively identified and a composition of the organic/inorganic hybrid gas barrier layer gradually changes.

FIG. 4 is a scan electron microscopic image of a cross-section of the gas barrier film of Example 1 cut in a depth direction thereof before and after a plasma treatment. The left image of FIG. 4 shows the precursor layer of Example 1 before the plasma surface treatment, and the right image of FIG. 4 shows the organic/inorganic hybrid gas barrier layer after the plasma treatment. After the plasma treatment, a portion of the precursor layer having a depth of up to 150 nm from the surface of the precursor layer was changed, and the portion includes an inorganic domain and a gradient domain.

Performance of the gas barrier films on the PES film base material prepared according to Examples and the gas barrier films prepared according to Comparative Examples was evaluated by using the following methods.

Analysis of Gas Barrier Film

X-Ray Photoelectron Spectrometer (XPS)

XPS (PHI-5800 electron spectrometer) was used to evaluate surface elements of the gas barrier films manufactured according to embodiments of the present invention and a depth-profile of the gas barrier films. The surface elements were evaluated by using Al Kα as a light source at an analysis diameter of 1 mm, an accelerating voltage of 15 kV, and an emission current of 26.67 mA, and a depth-profile of an element according to depth was measured while etching with 3.5 keV of Ar⁺ ions.

Scan Electron Microscope (SEM) Evaluation

The gas barrier film prepared according to Example 1 was cut and a cross-section of the cut gas barrier film was identified by scan electron microscope (Hitachi S-2500C).

Light Transmittance Evaluation

Light transmittance of the gas barrier films prepared according to Examples 1 to 21 was evaluated by using ultraviolet ray-visible ray spectrometer (HP 8453).

Pencil Hardness Evaluation

Surface hardness of the gas barrier films prepared according to Examples and Comparative Examples was evaluated by using a pencil hardness tester. Pencil hardness was measured as follows: a pencil for measuring a pencil hardness was inserted into a hardness tester at an angle of 45 degrees and the pencil tester was pushed to measure surface hardness while a predetermined weight was applied thereto. The pencils used herein were Mitsubishi pencils with rigidity of 1H to 9H, and F, HB, and B. A pencil hardness of the precursor layer formed before the plasma treatment was 1H (Comparative Example 2), and a surface hardness of Comparative Example 1 in which other element was not included and only silicon was used was 3H. However, a pencil hardness of an inorganic domain formed by the plasma treatment was in a range of 4H to 6H. Accordingly, it was confirmed that a surface hardness significantly increases due to the plasma treatment.

Refractive Index Evaluation

Refractive index of the organic/inorganic hybrid gas barrier layers of Examples and Comparative Examples was measured as follows: a layer was formed in the same manner as in Example 1 and Comparative Example 1, except that a silicon wafer was used as a base material, instead of the polymer base material, and then refractive index thereof was measured by using spectroscopic ellipsometer (Model: M-2000, manufacturer: J. A. Woollam). A refractive index of the organic/inorganic hybrid gas barrier layer before the plasma treatment was 1.51 (Example 1) or 1.42 (Comparative Example 1). After the plasma treatment, the refractive indexes were respectively increased to 1.56 (Example 1) and 1.48 (Comparative Example 1). In particular, when a metal precursor (aluminum) was used as an oxide precursor, a refractive index was high. This result shows that optical properties of an organic/inorganic hybrid gas barrier layer changes according to unique characteristics of a metal precursor.

Durability Evaluation

Durability of the organic/inorganic hybrid gas barrier layer prepared according to Example 9 was evaluated as follows: a bending distortion test was performed on the gas barrier layer, and a crack suppression capability and an oxygen transmission rate maintenance capability of the organic/inorganic hybrid gas barrier layer with respect to bending distortion were evaluated.

A bending motion test apparatus was manufactured based on ASTM D2236, and the gas barrier film of Example 9 was cut to a size of 100 mm×30 mm to prepare a sample, and then, a bending motion test was performed in a lengthwise direction of the sample, which is defined as a mechanical motion direction of the gas barrier film. In this regard, a frequency of the bending motion was 0.25 Hz, an angular displacement was (1/24)π, and a bending radius was 3 cm, and a repeating unit was 10,000.

Whether a crack was formed in the gas barrier film of Example 9 which underwent the bending motion test was identified under an optical microscope, and an oxygen transmission rate was measured at the temperature of 35° C. in relative humidity of 0%, and the obtained oxygen transmission rate was compared with the oxygen transmission rate of the gas barrier film before the bending motion test. Crack-resistance against bending was measured as follows: when a crack occurred after the bending, a corresponding evaluation value was indicated as ∘, when a crack did not occur, a corresponding evaluation value was indicated as x. In addition, gas blocking maintenance was evaluated as follows: when an oxygen transmission rate change after the bending was within ±10%, a corresponding evaluation value was indicated as ∘, and when an oxygen transmission rate change is outside the range above, a corresponding evaluation value was indicated as x.

Oxygen Transmission Rate Evaluation

Oxygen transmission rates (OTR) of the gas barrier films prepared according to Examples 1 to 21 and Comparative Examples 1 to 2 were measured by using an oxygen transmission rate measuring apparatus (Oxtran 2/20 MB, Mocon Company) at the temperature of 35° C. in relative humidity 0%. The results are shown in Table 2 below. (Oxtran 2/20 MB measurement limitation: <0.05 cm³/m²/day)

Such performance evaluation results are shown in Table 1 below.

TABLE 1

| | | Oxygen | | | | |
|---|---|---|---|---|---|---|
| | | transmission | Light | | | |
| | Molar ratio of other | rate | transmittance | Refractive | Pencil | |
| | element: Si | (cm³/m²/day) | (550 nm) | index | hardness | crack |
| Example 1 | Al:Si = 1:2 | Less than | 87% | 1.56 | 5H | X |
| | | 0.05 | | | | |
| Example 2 | Ti:Si = 1:1 | Less than | 88% | 1.98 | 6H | X |
| | | 0.05 | | | | |
| Example 3 | Zr:Si = 1:3 | 0.14 | 86% | 1.63 | 5H | X |
| Example 4 | Zn:Si = 1:2 | 0.15 | 87% | 1.64 | 5H | X |
| Example 5 | Mg:Al:Si = 1:2:8 | Less than | 86% | 1.54 | 5H | X |
| | | 0.05 | | | | |
| Example 6 | B:Al:Si = 1:1:4 | Less than | 87% | 1.52 | 6H | X |
| | | 0.05 | | | | |
| Example 7 | B:Si = 1:5 | 0.12 | 88% | 1.51 | 5H | X |
| Example 8 | P:Si = 1:1 | 0.05 | 85% | 1.45 | 4H | X |
| Example 9 | Ga:Si = 1:7 | 0.29 | 87% | 1.52 | 5H | X |
| Example 10 | Al:Si = 1:3 | 0.09 | 88% | 1.54 | 5H | X |
| Example 11 | Al:Si = 1:5 | 0.16 | 88% | 1.51 | 4H | X |
| Example 12 | Ge:Si = 1:6 | 0.23 | 87% | 1.49 | 4H | X |
| Example 13 | Tl:Si = 2:1 | Less than | 88% | 2.09 | 6H | X |
| | | 0.05 | | | | |
| Example 14 | Mg:B:Si = 1:5:10 | Less than | 85% | 1.49 | 5H | X |
| | | 0.05 | | | | |
| Example 15 | Sn:Si = 1:4 | 0.22 | 87% | 1.57 | 5H | X |
| Example 16 | Zr:Si = 1:2 | 0.06 | 86% | 1.68 | 6H | X |
| Example 17 | Ti:Si = 1:3 | 0.11 | 88% | 1.72 | 6H | X |
| Example 18 | Al:Si = 1:5 | 0.14 | 88% | 1.51 | 4H | X |
| Example 19 | Al:Si = 1:5 (stacking of | Less than | 86% | — | 5H | X |
| | double layer on the same | 0.05 | | | | |
| | surface) | | | | | |
| Example 20 | Al:Si = 1:5 (both-sided) | Less than | 84% | — | 5H | X |
| | | 0.05 | | | | |
| Example 21 | Al:Si = 1:10 | 0.07 | 87% | 1.51 | 4H | X |
| Comparative | Oxide precursor of other | 0.42 | 87% | 1.48 | 3H | X |
| Example 1 | element was not included | | | | | |
| Comparative | Al:Si = 1:2 (not treated with | 310 | 88% | 1.45 | 1H | — |
| Example 2 | plasma) | | | | | |
| Comparative | Vacuum deposited SiOx | 0.30 | 88% | 1.46 | 5H | ◯ |
| Example 3 | gas barrier layer | | | | | |

The organic/inorganic hybrid gas barrier layers of Examples all showed excellent oxygen blocking properties and optical characteristics (light transmittance and refractive index) suitable for display purpose although they have various compositions. The organic/inorganic hybrid gas barrier layers of Examples, due to an inorganic domain that contains two or more inorganic atoms including silicon and other element and is formed by plasma treatment, had high surface hardness, and due to the buffering of the gradient domain, had durability on bending distortions (crack suppression, and oxygen blocking maintenance). That is, the gas barrier layers had rigidity, hardness, and flexibility.

In detail, when the gas barrier layer of Comparative Example 1 that is formed of only organosilane and silicate ester without the other element and is heat treated is compared with the organic/inorganic hybrid gas barrier layers of Examples, it was confirmed that the surface hardness of Comparative Example 1 is far below that of Example, and although the oxygen transmission rate of Comparative Example 1 is at a suitable level, it is still high than that of Example. When the plasma treatment was omitted as in Comparative Example 2, gas blocking effects were negligible. Accordingly, the gas barrier layer of Comparative Example 2 was not suitable for use as a gas barrier layer. In addition, due to the absence of the inorganic domain, as expected, the surface hardness was relatively too low. As described above, since the gas barrier layer of Comparative Example 2 did not include an inorganic domain, a bending distortion test was not performed on the gas barrier layer. Unlike the formation of an inorganic domain by plasma treatment according to the present invention, the gas barrier layer of Comparative Example 3 includes an inorganic layer deposited in a vacuum condition. The gas barrier layer of Comparative Example 3 had oxygen blocking characteristics that are similar to or lower than that of Example. In addition, the gas barrier layer of Comparative Example 3 having a stack structure of an organic layer and an inorganic layer, not the compositionally gradient structure, had a substantially low resistance to bending distortions of the gas barrier film, so that gas barrier layer cracks and an oxygen transmission rate thereof was increased substantially.

From data shown in Table 1 it was confirmed that a gas barrier film according to an embodiment of the present invention has excellent gas blocking properties and mechanical strength of an inorganic material and flexibility of an organic material, and due to the inclusion of a plurality of inorganic elements, a surface hardness and optical characteristics were improved. It was also confirmed that according to the method of manufacturing a gas barrier film according to an embodiment of the present invention, without the requirement for high vacuum conditions, a gas barrier film with excellent characteristics was formed by using a wet process only.

A gas barrier film that has excellent gas blocking properties, transparency, and high adhesive force with respect to a base material may be stably and economically formed by using a simple manufacturing process. Also, a gas barrier film that has flexibility, high hardness and strength, and controllable refraction index and transparency may be obtained, and the gas barrier film may be suitable for use in display panels and solar cells.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A gas barrier film comprising:
a base material; and
an organic/inorganic hybrid gas barrier layer that is formed on the base material and has a compositionally gradient structure,
wherein the organic/inorganic hybrid gas barrier layer has a network structure comprising —O—Si—O— linkages,
wherein the network structure contains
an organic functional group having a carbon atom directly linked to a silicon atom of the —O—Si—O— linkages, and
other element that exists in an oxide form in the interstitial location of the network structure or that is linked to an oxygen atom of the —O—Si—O— linkages,
wherein the other element comprises at least one selected from alkali metal, alkaline earth metal, transition metal, post transition metal, metalloid, boron, and phosphorous.

2. The gas barrier film of claim 1, wherein
the organic/inorganic hybrid gas barrier layer having compositionally gradient structure comprises an inorganic domain, an organic domain, and a gradient domain,
the inorganic domain is a domain of the organic/inorganic hybrid gas barrier layer which is away from the base material, and from which carbon is not substantially detected;
the organic domain is a domain of the organic/inorganic hybrid gas barrier layer which is near to the base material, and from which carbon is detected in a predetermined amount; and
the gradient domain is a domain of the organic/inorganic hybrid gas barrier layer that is interposed between the inorganic domain and the organic domain, and that has a carbon content gradually monotone-increasing in a thickness direction from the inorganic domain to the organic domain.

3. The gas barrier film of claim 1, wherein
an atomic number ratio of the other element to the silicon atom is in a range of 1:20 to 20:1.

4. The gas barrier film of claim 1, wherein
a refractive index of the organic/inorganic hybrid gas barrier layer having the compositionally gradient structure is in a range of 1.1 to 2.5 with respect to light having a wavelength of 632 nm at a temperature of 25° C.

5. The gas barrier film of claim 2, wherein
the carbon content of the inorganic domain satisfies the following relationship:
$$\frac{{N}_{carbon}}{{N}_{silicon} + {N}_{oxygen} + {N}_{other element} + {N}_{carbon}} \leq 0.05$$
wherein N_{carbon} is the number of carbon atoms, N_{silicon} is the number of silicon atoms, N_{oxygen} is the number of oxygen atoms, N_{other element} is the number of other elements.

6. The gas barrier film of claim 2, wherein
a surface hardness of the inorganic domain measured by using a pencil hardness tester is 6H or higher.

7. The gas barrier film of claim 1, wherein
the other element comprises at least one selected from Li, Na, K, Rb, Cs, Be, Mg, Ca, Sr, Ba, Ti, Zr, Hf, V, Nb, Mo, W, Te, Re, Ni, Zn, Al, Ga, In, TI, Sn, B, and P.

8. The gas barrier film of claim 1, wherein
the base material is selected from polyethylene terephthalate, biaxially-oriented polyethylene terephthalate (BOPET), polyethersulfone, polycarbonate, polyimide, polyarylate, polyethylenenaphthalate, epoxy resin, unsaturated polyester, low-density polyethylene (LDPE), middle-density polyethylene (MDPE), high-density polyethylene (HDPE), linear low-density polyethylene (LLDPE), biaxially-oriented polypropylene (BOPP), oriented polypropylene (OPP), cast polypropylene (CPP), biaxially-oriented polyamide (BOPA), cycloolefin copolymer, fiber reinforced plastics, glass, metal, and a composite material thereof.

9. The gas barrier film of claim 1, wherein
an oxygen transmission rate of the gas barrier film is in a range of 10⁻¹ cm³/m²/day to 10⁻³ cm³/m²/day at the temperature of 35° C. in a relative humidity of 0%.

10. A substrate for an electronic device, comprising the gas barrier film of claim 1.

11. An electronic device comprising the gas barrier film of claim 1.

12. A packaging material, comprising the gas barrier film of claim 1.

13. A method of manufacturing a gas barrier film, the method comprising:
performing a sol-gel reaction on an organic/inorganic mixed solution including at least one organosilane represented by Formula 1 below, at least one silicate ester represented by Formula 2 below, and an oxide precursor of at least one other element selected from alkali metal, alkaline earth metal, transition metal, post transition metal, metalloid, boron, and phosphorous, to form a coating solution;
coating and curing the coating solution on a base material to form an organic/inorganic hybrid precursor layer, and
treating a surface of the organic/inorganic hybrid precursor layer with plasma of reactive gas to form an organic/inorganic hybrid gas barrier layer having a compositionally gradient structure:
A¹ₗA²ₘA³ₙSi(OE¹)ₚ(OE²)_{q}(OE³)ᵣ [Formula 1]
Si(OG¹)_{α}(OG²)_{β}(OG³)_{γ}(OG⁴)_{δ} [Formula 2]
wherein in Formulae 1 and 2, A¹, A², and A³ are each independently a C1 to C20 alkyl group, a C1 to C20 fluoroalkyl group, a C6 to C20 aryl group, a vinyl group, an acryl group, a methacryl group, or an epoxy group,
l, m, and n are each independently an integer of 0 to 3 and satisfy 1≦l+m+n≦3,
E¹, E², and E³ are each independently a C1 to C10 alkyl group, a C1 to C10 fluoroalkyl group, a C6 to C20 aryl group, a C1 to C20 alkyloxyalkyl group, a C1 to C20 fluoroalkyloxyalkyl group, a C1 to C20 alkyloxyaryl group, a C6 to C20 aryloxyalkyl group, or a C6 to C20 aryloxyaryl group,
p, q, and r are each independently an integer of 0 to 3 and satisfy 1≦p+q+r≦3 and l+m+n+p+q+r=4,
G¹, G², G³, and G⁴ are each independently a C1 to C10 alkyl group, a C1 to C10 fluoroalkyl group, a C6 to C20 aryl group, a C1 to C20 alkyloxyalkyl group, a C1 to C20 fluoroalkyloxyalkyl group, a C1 to C20 alkyloxyaryl group, a C6 to C20 aryloxyalkyl group, or a C6 to C20 aryloxyaryl group, and
α, β, γ, and δ are each independently an integer of 0 to 4 and satisfy the equation of α+β+γ+δ=4.

14. The method of claim 13, wherein
the oxide precursor of the other element is a precursor that is capable of forming a diatomic oxide of the other element and oxygen through a sol-gel reaction.

15. The method of claim 13, wherein
the organosilane compound is a compound represented by Formula 3, and
the silicate ester compound is a compound represented by Formula 4:
R¹ₓSi(OR²)₍₄₋ₓ₎ [Formula 3]
Si(OR³)₄ [Formula 4]
wherein in Formulae 3 and 4,
R¹ is a C1 to C20 alkyl group, a C1 to C20 fluoroalkyl group, a C6 to C20 aryl group, a vinyl group, an acryl group, a methacryl group or an epoxy group;
R² is a C1 to C10 alkyl group, a C1 to C10 fluoroalkyl group, a C1 to C20 alkyloxyalkyl group, or a C1 to C20 fluoroalkyloxyalkyl group; and
x is an integer of 1 to 3; and
R³ is a C1 to C10 alkyl group or a C1 to C20 alkyloxyalkyl group.

16. The method of claim 13, wherein
the silicate ester compound represented by Formula 2 is mixed at a molar ratio of 1:10 to 10:1 with respect to the organosilane compound represented by Formula 1.

17. The method of claim 13, wherein an amount of organosilane satisfies the following relationship:
$$0.05 \leq \frac{{M}_{organosilane}}{{M}_{silicate ester} + {M}_{other element}} \leq 5$$
wherein M_{organosilane} is a molar number of the organosilane compound represented by Formula 1, M_{silicate ester} is a molar number of the silicate ester compound represented by Formula 2, and M_{other element} is a molar number of the other element in the oxide precursor of the other element.

18. The method of claim 13, wherein
the organic/inorganic mixed solution further comprises water in such an amount that a ratio of a molar number of water to a total molar number of hydrolyzable functional groups of the organosilane compound represented by Formula 1, the silicate ester compound represented by Formula 2, and the oxide precursor of the other element is in a range of 1:5 to 5:1.

19. The method of claim 13, wherein
in preparing the organic/inorganic mixed solution, a molar number of the oxide precursor of the other element is in a range of 0.01 to 10 based on the total molar number of the organosilane compound represented by Formula 1, and the silicate ester compound represented by Formula 2.

20. The method of claim 13, wherein
the plasma comprising reactive gas is generated from a source gas selected from oxygen, nitrogen monoxide (N₂O), nitrogen, ammonia, hydrogen, water vapor, a mixture thereof, and a mixture of these gas and inert gas.
